(19) United States
(12) Patent Application Publication
(10) Pub. No.: US 2017/0153283 A1
(43) Pub. Date: Jun. 1, 2017

(54) METHOD FOR DETECTING PERMANENT AND INTERMITTENT FAULTS IN A SET OF WIRES TO BE TESTED

(71) Applicant: NEXEYA SYSTEMS, Toulouse (FR)

(72) Inventors: Patrick GONTIER, Tournefeuille (FR); Jérôme DAURELLE, La Salvetat-Saint-Gilles (FR); Lionel RODRIGUEZ, Longages (FR)

(73) Assignee: NEXEYA SYSTEMS, Toulouse (FR)

(21) Appl. No.: 15/308,927

(22) PCT Filed: May 6, 2015
(86) PCT No.: PCT/FR2015/051205

§ 371 Date: Jan. 24, 2017

(30) Foreign Application Priority Data
May 6, 2014 (FR) 14 54089

(51) Int. Cl. G01R 31/08; G01R 31/11; G01R 31/02

(52) U.S. Cl. CPC G01R 31/083; G01R 31/021; G01R 31/11

(57) ABSTRACT

The invention relates to a method for detecting faults in a set of wires (25) to be tested comprising at least two wires each having an input end and an output end. The method comprises in succession a step (10) of connecting at least one wire undergoing analysis to a signal generator (26) and of grounding the other wires, a step (12) of generating a test signal on the channel undergoing analysis with the signal generator (26), a step (13) of acquiring and measuring the power of a first signal returned over at least one wire connected to the acquiring unit (29), and a step (14) of analyzing the integrity of the wire undergoing analysis using the power of the return signal of the wire in question and the analyzing unit (31). These steps repeat automatically, the wire to be tested being changed each time.

### FIELD OF THE INVENTION

The present invention relates to a method for detecting permanent and intermittent faults in a set of wires to be tested. It relates in general to the field of electrical tests. It relates more particularly to the detection of faults in electrical cables.

In particular, the invention has applications in various sectors such as the aerospace, automotive, railroad, and industrial sectors.

### BACKGROUND

The length of the cables on board an aircraft and the number of connections have increased more than tenfold over the past thirty years. In addition, the arrival of “wired” technology and everything being electrical gives paramount importance to electrical connections, as they are becoming the only link between the pilot, his actions, and the vehicle. Wiring reliability is therefore of primary interest in aerospace as well as in any type of industry.

A wire will degrade over time and under the various stresses it is subjected to, and faults in the wire will then occur. These faults change the electrical behavior of the wire and can eventually lead to failures of more or less significance in the systems it connects. For reasons of quality of service, cost, and safety, it is necessary to anticipate such failures and therefore to be able to diagnose the condition of the cables, meaning to detect and characterize faults in the cabling.

Reflectometry is one diagnostic method used for electrical characterization of cables. It involves injecting a signal into a wire undergoing analysis. This signal propagates along the wire and when it encounters a discontinuity, a portion of its energy is reflected back to the point of injection. Analysis of the reflected signal provides information about the wire, such as a fault.

It is known to use a reflectometry method when wanting to detect permanent degradation of a wire. However, it is much more difficult to detect and determine the location of intermittent faults, due to the very short period during which these faults interfere with the system and due to the variation of said period over time.

US document 2004/0232919 relates to a non-intrusive, fully automated, variable cable and impedance-based, multiplexed cable testing system, the system using time domain reflectometry techniques. This system can handle multiple types of cables with varying characteristics at any one time, during which time the system confirms and processes both the characteristics of the type of cable under test and any discontinuities encountered during operational life of said cable, due to the impedance variations defined and processed. Furthermore, this system provides an extensive real time prognostic and diagnostic data, together with accurate location and interpretation of any said data and/or discontinuity including, but not limited to, the additional mapping of impedance variations along the length of the cable.

The most common intermittent faults are usually problems from crimping or from damaged wires creating a short-circuit during vibrations. These faults are usually seen by the surrounding systems.

Current methods for detecting faults using reflectometry only allow analyzing one wire at a time. However, a wire is rarely alone but instead is grouped in a structure called a bundle, cable, or harness. The current methods therefore require tedious and time-consuming manual manipulation by a user in order to detect faults in a set of wires.

### SUMMARY

The invention aims to eliminate or at least mitigate some or all of the aforementioned disadvantages of the prior art.

An object of the invention is therefore to propose a method for diagnosing faults in cables which allows detecting faults in grouped electrical wires.

In particular, the present invention aims to provide a method for detecting faults which is fast and efficient. In the case of an aeronautical application, the detection method advantageously allows the detection of intermittent faults for example in 512 wires of a length of approximately 100 m within a duration of about 1 ms.

The method preferably detects both intermittent and permanent faults, in particular open circuit and/or short-circuit to ground and/or short-circuit between two wires of a same harness.

The invention also aims to provide a simple diagnostic method that limits the number of manual manipulations.

A method for detecting faults according to the invention will preferably also be easy to regulate and/or of high reliability and/or of moderate cost.

To this end, the invention proposes a method for detecting faults in a set of wires to be tested comprising at least two wires each having a first end, the input end, and a second end, the output end.

According to the invention the method uses:

a signal generator,

an electrical ground,

a switching matrix providing a set of channels respectively connected to the input ends of the wires to be tested, and whose function is to connect the wires to be tested either to the electrical ground or to the signal generator and to select one of the channels for analysis of a return signal,

a set of end loads connected to the output ends of each wire,

an acquisition unit adapted for measuring the return signal,

an analysis unit, and

a control unit,

and comprises the following steps in succession:

selecting and connecting at least one wire to be analyzed to the signal generator, and grounding the other wires,

generating a test signal on the wire to be analyzed, using the signal generator,

measuring the power of a return signal on at least one of the connected wires, using the acquisition unit,

analyzing the power of the return signal on the wire considered, using the analysis unit, and

determining the integrity of the wire undergoing analysis,

the steps of said method repeating automatically, the wire to be tested changing each time.

A first test phase is thus defined by the generation step, the measurement step, and the determination step.

It was found that this fault detection method allows reducing user intervention by automatically testing the different wires in succession. In addition, tests have shown that such a method is particularly well-suited for the detection of intermittent faults and provides good reliability. In particular, this method can detect non-permanent faults in a reliable and timely manner, using reflectometry.

One embodiment provides that the detection method comprises the following successive steps if at least one wire of the set of wires is diagnosed as having impaired integrity:

generating a location signal on a wire diagnosed as having impaired integrity, using the signal generator,

measuring a second return signal on said wire diagnosed as having impaired integrity, using the acquisition unit,

analyzing said wire diagnosed as having impaired integrity, by reflectometry, using the analysis unit, and

determining the position of the fault in said wire diagnosed as having impaired integrity.

A second test phase is thus defined by the generation step and the measurement step.

Advantageously, this second test phase as well as the analysis step and the determination step allow, by reflectometry, precisely pinpointing the location along the wire concerned of the fault detected during the first test phase. Thus, the invention helps facilitate the maintenance of wire harnesses.

In an alternative embodiment of the invention, determining the position of the fault is achieved by:

frequency shifting the return signal based on a frequency-modulated location signal, and/or

time shifting the propagation of the return signal based on a location signal in pulse form, and/or

pulse compression of the return signal based on a frequency-modulated location signal truncated by a gate function.

Advantageously, the second phase comprises a location signal having a bandwidth of around 320 MHz.

In addition, according to one embodiment of the invention, the generated test signal is a low frequency signal, in particular between 500 kHz and 5 MHz.

Advantageously, the test signal is in particular about 1 MHz.

Also proposed is a detection method capable of storing a measurement of the return signals relative to the test signals, for each wire tested. Said detection method can then compare the current measurement to previously stored measurements, enabling preventive maintenance for the set of wires.

Advantageously, the act of storing and comparing various measurements collected over time for a same wire allows anticipating faults. This facilitates cable maintenance.

The proposed detection method may also be able to characterize a set of wires. To do so, the method uses for example an LCR meter and an LCR switching matrix having a set of channels respectively connected to the input ends of the wires to be tested, and whose function is to connect the wires to be tested either to the electrical ground or to the LCR meter, and comprises the following steps in succession:

selecting at least two wires to be analyzed and connecting them to the LCR meter, and grounding the other wires,

generating a measurement signal using the LCR meter,

measuring the resistance and/or measuring the inductance and or measuring the capacitance, and

characterizing the wires undergoing analysis.

The invention further relates to a mobile device comprising the necessary means for implementing all the steps of a fault detection method as described above.

Such a device according to the invention thus comprises, for example:

a signal generator,

an electrical ground,

a switching matrix providing a set of channels respectively connected to the input ends of the wires to be tested, and whose function is to connect the wires to be tested either to the electrical ground or to the signal generator and to select only one of the channels for analysis of a return signal,

a set of end loads connected to the output ends of each wire,

an acquisition unit adapted for measuring the return signal,

an analysis unit, and

a control unit.

Such a device may be such that the switching matrix is a high frequency switching matrix having a set of channels respectively connected to the input ends of the wires to be tested, whose function is to connect the wires to be tested either to the electrical ground or to the signal generator and to select only one of the channels for analysis of a return signal.

The switching matrix advantageously comprises at least one FET transistor operating as a switch, allowing very fast switching.

Advantageously, such a switching matrix allows a fault detection method of the invention to change automatically the wire to be tested, without any user intervention. The matrix therefore contributes to automation of a method according to the invention.

In addition, the switching speed of this matrix allows a method of the invention to detect faults in a set of wires very quickly.

The use of such a device allows, for example, detecting faults in 1024 wires of an approximate length of 100 m within about 2 ms, or detecting faults in 512 wires of an approximate length of 100 m within about 1 ms.

In one advantageous embodiment of the invention, the matrix, the acquisition unit, the analysis unit, and control unit are located in a single circuit board.

In one embodiment, a device further comprises a computer having a software interface which allows remotely controlling the fault detection method. This advantageously makes it possible to move the unit about while controlling it remotely by means of a software interface, and thus facilitates its use.

Finally, the invention relates to a unit further comprising an LCR meter connected by means of an LCR switching matrix to the set of wires to be tested, to enable fault detection by resistance measurements, inductance measurements, and capacitance measurements.

Advantageously, an LCR type of measurement allows accurately characterizing permanent faults.

A fault detection device as described above may be included in a portable tester which can be used on more than one apparatus or may be embedded within an apparatus.

### BRIEF DESCRIPTION OF THE DRAWINGS

Details and advantages of the invention will become more apparent from reading the following description with reference to the accompanying drawings in which:

FIG. 1 is an activity diagram illustrating one embodiment of the invention,

FIG. 2 is an activity diagram illustrating a variant of the embodiment illustrated in FIG. 1,

FIG. 3 is a diagram representing a method for detecting and locating faults according to one embodiment of the invention,

FIG. 4 is a block diagram illustrating a fault detection device according to the invention, and

FIG. 5 is a summary view illustrating one embodiment of an implementation of a fault detection device.

### DETAILED DESCRIPTION OF THE PREFERRED EMBODIMENTS

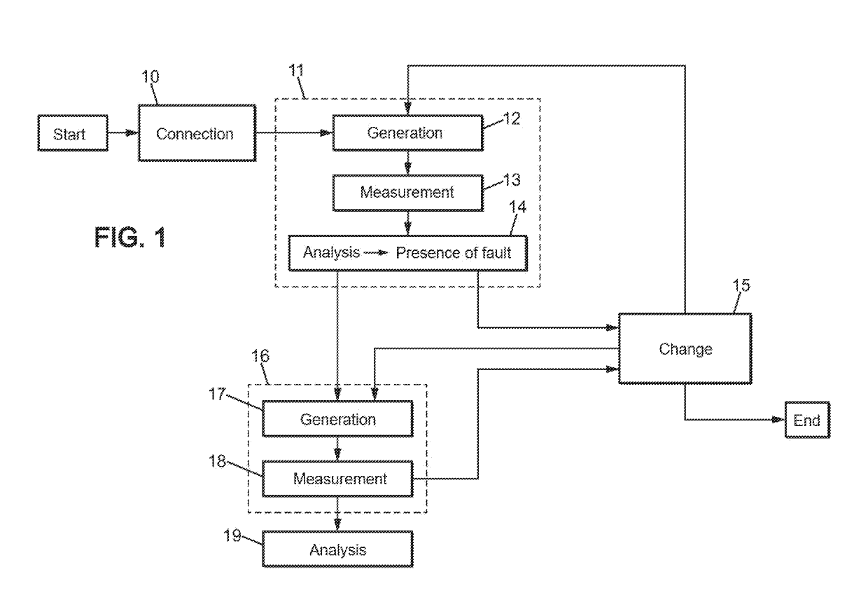

FIG. 1 illustrates the general flow of one embodiment of a fault detection method according to the invention.

The invention relates to a fault detection method. Detected faults are likely to cause failures and are for example intermittent, non-permanent, or transient. The detection method also advantageously detects permanent faults.

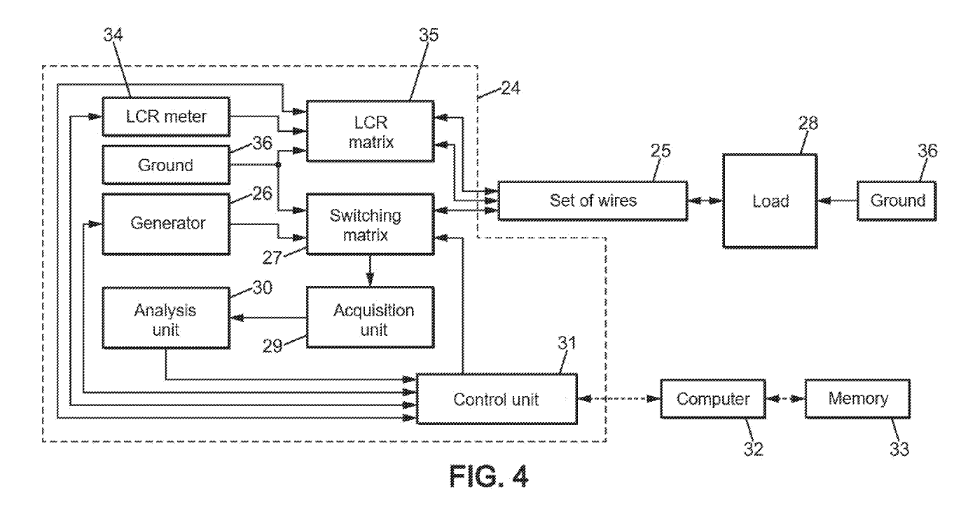

This method applies to a set of wires 25 (shown in FIG. 4) to be tested. The method is advantageously applied to all wires of a same harness.

It is assumed in this exemplary embodiment that the wires are each a single wire, but the detection method of the invention may be applied to any type of wire.

The wires each have a first end, the input end, and a second end, the output end. Each output end is connected to a suitable end load, for example a resistive load, and each input end is connected to a device included in a unit 24 (shown in FIG. 4) for the detection of faults. There are therefore preferably as many loads as there are wires to be tested. Each load is connected to an output end of a wire to be tested and to an electrical ground 36 (shown in FIG. 4).

This fault detection method proposes a first connection step 10 during which each input end of the various wires to be tested is connected to a signal generator 26 or to the electrical ground 36 or to an acquisition unit 29 by means of a switching matrix 27 (these components being represented in FIG. 4), and each output end of the wires is connected to each end load.

Thus, in this exemplary embodiment, an input end of a first wire to be tested receives a first test signal while the other input ends of the other wires of the set of wires 25 to be tested are connected to ground 36. The wire receiving the first test signal is the wire whose integrity will be determined, and is said wire undergoing analysis.

The fact that the wires that are not the wire undergoing analysis are connected to ground 36 advantageously avoids creating parasitic capacitance and allows more reliable measurements. In addition, this allows automatically increasing the number of wires to be tested without degrading the measurement.

Once the connections are in place, the method comprises a first test phase 11 for detecting whether or not there is a fault in the set of wires 25. The first phase 11 comprises a plurality of fault detection sub-phases, each having a generation step 12, an acquisition and measurement step 13, and an analysis step 14. Each time the method changes the wire to be tested, a detection sub-step is applied to the wire undergoing analysis.

To do this, the generation step 12 sends a test signal on the wire undergoing analysis. This test signal is, for example, a low frequency signal, in particular between 500 kHz and 5 MHz, and preferably about 1 MHz.

The first test signal is propagated along the wire currently undergoing analysis until it reaches the end load. A first return signal corresponds to the superposition of the signals reflected in the wire currently undergoing analysis and on the end load.

The proposed method then provides the step 13 of capturing and measuring the first return signal, during which the power of the first return signal is measured.

According to one embodiment, at least one input end of one of the wires not currently undergoing analysis is not connected to ground 36. The first return signal of the wire currently undergoing analysis can then be captured on the wire whose input end is not connected to ground 36 even if this wire is not the wire currently undergoing analysis. It is thus possible to detect a connection between two wires in the set of wires 25.

The first return signal is then analyzed in the analysis step 14, in order to determine whether there is a fault in the wire currently undergoing analysis. This analysis is done by comparing the power of the test signal and that of the first return signal. Using a certain predetermined threshold for the difference in power between the two signals, the wire currently undergoing analysis is diagnosed as failing or not failing the integrity check.

Once the analysis is done, the inlet end of the first wire is connected to ground by the switching matrix 27, thereby defining a wire change step 15. A second test signal having the same characteristics as the first test signal is then transmitted to an input end of a second wire of the set of wires 25 to be tested.

Another detection sub-phase comprising a generation step 12, an acquisition and measurement step 13, and an analysis step 14 is then carried out.

A wire change step 15 is automatically repeated as many times as necessary, meaning at least as many times as there are wires to be tested.

When a fault is detected during the first phase 11, the detection method proposes a second test phase 16 to locate the fault by reflectometry. This second phase 16 is applied only to the wires that the first phase 11 determined to have impaired integrity.

This second test phase 16 comprises a plurality of fault location sub-phases. Each location sub-phase successively has a generation step 17 and an acquisition and measurement step 18. Each time the method changes the wire to be tested, a location sub-phase is applied to the wire currently undergoing analysis. The various sub-phases of the second phase 16 may advantageously implement at least one of the following three reflectometry methods: frequency domain reflectometry (FDR), time domain reflectometry (TDR), and/or pulse compression.

During the generation step 17, a location signal is sent over the wire undergoing analysis that contained a fault. The location signal preferably has a frequency band of about 320 MHz.

During the acquisition and measurement step 18, a second return signal, corresponding to a superposition of the signals reflected in the wire currently undergoing analysis and on the end load, is captured at the input end of the wire currently undergoing analysis.

After each location sub-phase, the method allows either continuing to detect faults in a “continuous” mode of the method via the wire change step 15, or stopping detection when the first fault is detected in a “stop at detection” mode of the method.

The method may further comprise a step 19 of analyzing the second return signal in order to locate the fault on the wire currently undergoing analysis.

A method using TDR reflectometry consists of sending a pulse or a voltage level on the wire as a location signal during the generation step 17. The second return signal is then in the form of a succession of peaks, corresponding to reflections of the location signal at discontinuities or faults in the wire undergoing analysis. Thus, during the analysis step 19, the nature and position of the fault are respectively determined by the amplitude and propagation delay of the detected peaks, the signal propagation speed being known. The nature and position of the fault may also be determined by comparing the measurement made in the acquisition and measurement step 18 to a fault-free initial measurement serving as a baseline, the length of the wire being known. Advantageously, a plurality of signal types may be used, for example a gate function or a Heaviside step function, or a Gaussian pulse.

In a method using FDR reflectometry, the location signal is a frequency-modulated signal. The acquisition and measurement step 18 and the analysis step 19 may consist either of measuring the frequency shift between the location signal and the corresponding second return signal, or of measuring the phase shift between the location signal and the corresponding second return signal, in order to locate the fault.

In the pulse compression method, the location signal used is advantageously a frequency modulated sinusoidal signal truncated by a gate function.

The first test phase 11 thus allows detecting faults in the set of wires 25. Once the presence of at least one fault is detected, the second test phase 16 allows locating the faults along the tested wire.

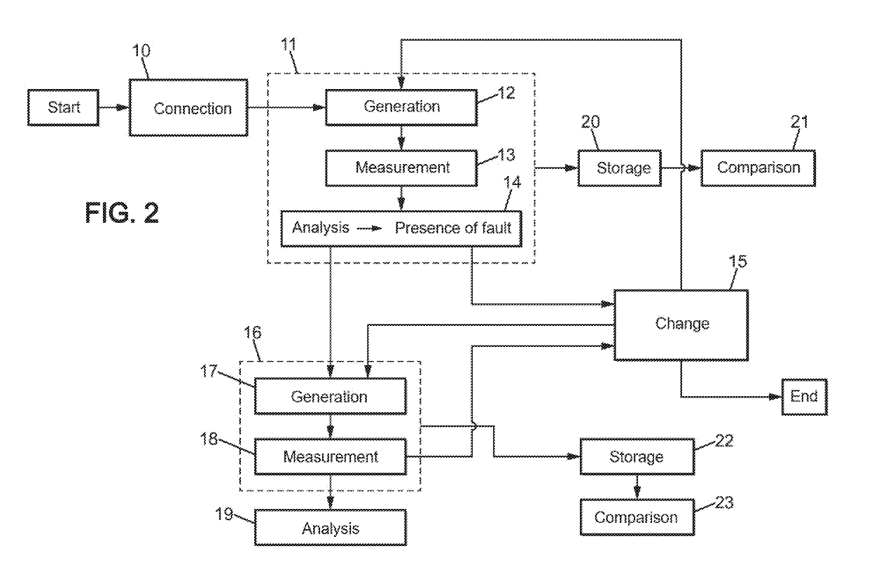

FIG. 2 illustrates the general flow of an alternative embodiment of the fault detection method presented above. In this alternative embodiment, the fault detection method further comprises a first storage step 20 where each power measurement is stored for the first return signal, during each detection sub-phase.

The measurement storage step 20 allows subsequently performing a first comparison step 21 where the current measurement for the wire undergoing analysis is compared to the various measures already stored for the same cable during previous tests.

Similarly, the fault detection method may also advantageously comprise a second storage step 22 where each measurement of the second return signal obtained by reflectometry during each location sub-phase is stored, and a second comparison step 23 where the current measurement for the wire undergoing analysis is compared to the various measurements already stored for the same wire during previous tests.

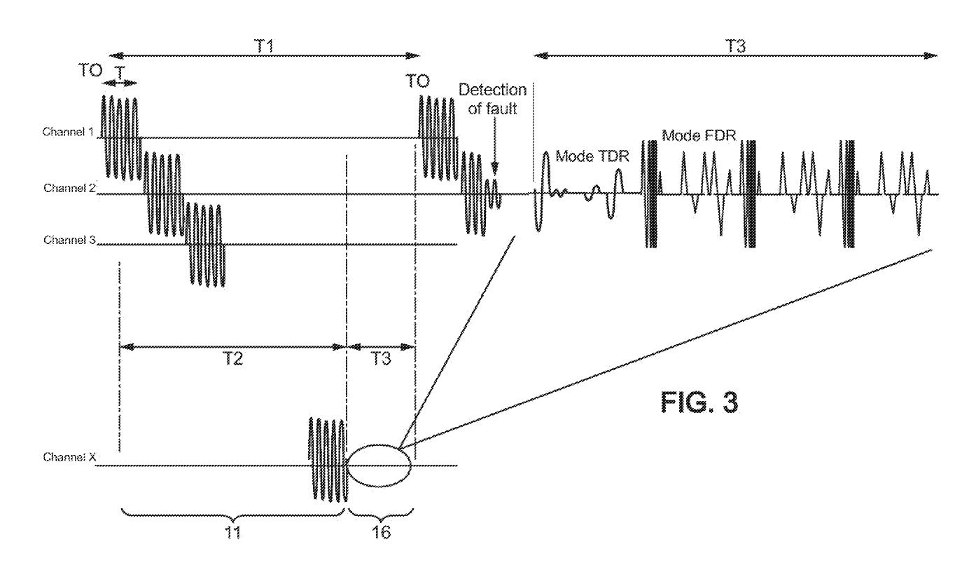

FIG. 3 shows a timing diagram representing a method for detecting and locating faults according to an embodiment of the present invention.

In this embodiment, a total duration T1 of the method includes the first phase 11 of duration T2, for fault detection, followed by the second phase 16 of duration T3, for fault location. T represents the duration of a first detection sub-phase on a cable. As described above, a first detection sub-phase is performed on a first wire to be tested, here on channel 1, then successively a second detection sub-phase is performed on a second wire to be tested, here on channel 2, and so on until all wires have been tested.

In the example of FIG. 3, a fault is detected on channel 2 due to a reduction in the power of the return signal relative to the corresponding test signal. The second phase 16 is then performed on channel 2 after the first phase 11 is completed. FIG. 3 shows a TDR reflectometry method followed by an FDR reflectometry method in order to locate the fault.

For a numerical and purely illustrative non-limiting example, for a set of wires 25 containing 512 simple wires of a length of 100 m, T1 is approximately equal to 1 ms, T is about 1.4 μs, T2 is about 700 μs, and T3 is about 300 μs. With a propagation time of approximately 7 ns in 1 m of electrical wire, we obtain a total roundtrip propagation time on a 100 m wire of about 1.4 μs. Thus, the first test phase for 512 wires lasts approximately 716 μs. A fault location sub-phase lasts for less than 150 μs.

FIG. 4 is a block diagram illustrating a device for implementing a detection method as described above.

For its deployment, the fault detection method comprises a set of wires 25 to be tested, connected at an output end to a set of loads 28 and at the input end to the unit 24 for detecting and locating faults.

The detection device is included in the unit 24 and comprises:

a portion intended for detecting non-permanent and permanent faults, comprising the signal generator 26, the electrical ground 36, the switching matrix 27, the acquisition unit 29, and an analysis unit 30, and

a portion intended for characterizing the set of wires 25, comprising an LCR meter 34, the ground 36, and a switching matrix 35.

The unit 24 further comprises a control unit 31 for the above two portions.

The function of the signal generator 26 included in the unit 24 is to generate the test signals and location signals used respectively during the first phase 11 of detecting intermittent faults and the second phase 16 of locating the detected faults. The generator 26 is connected via the switching matrix 27 to the input ends of each wire in the set of wires 25.

The switching matrix 27 has an input channel that connects the input ends of the wires either to the generator 26 or to ground 36. It also has a set of output channels comprising at least as many channels as there are wires to be tested. The switching matrix 27 further has an output channel to the acquisition unit 29.

The switching matrix 27 is a high frequency switching matrix and advantageously comprises a plurality of FET transistors operating in switching mode.

Each output end of the wires to be tested is connected to a load among the set of loads 28. These loads, intended to adjust each wire to be tested, are resistive loads. These are preferably resistive loads having a given value of 50Ω.

The acquisition unit 29 carries out the acquisition and measurement steps 13 and acquisition and measurement steps 18.

The function of the analysis unit 30 is to carry out the analysis steps 14 and analysis steps 19. It also has the function of determining the integrity of the wire undergoing analysis and locating the faults.

The control unit 31 is a processor that centralizes, controls, and synchronizes preferably all components of the device. The control unit 31, also called a processing unit, is based on an FPGA structure which enables it to perform these functions in parallel.

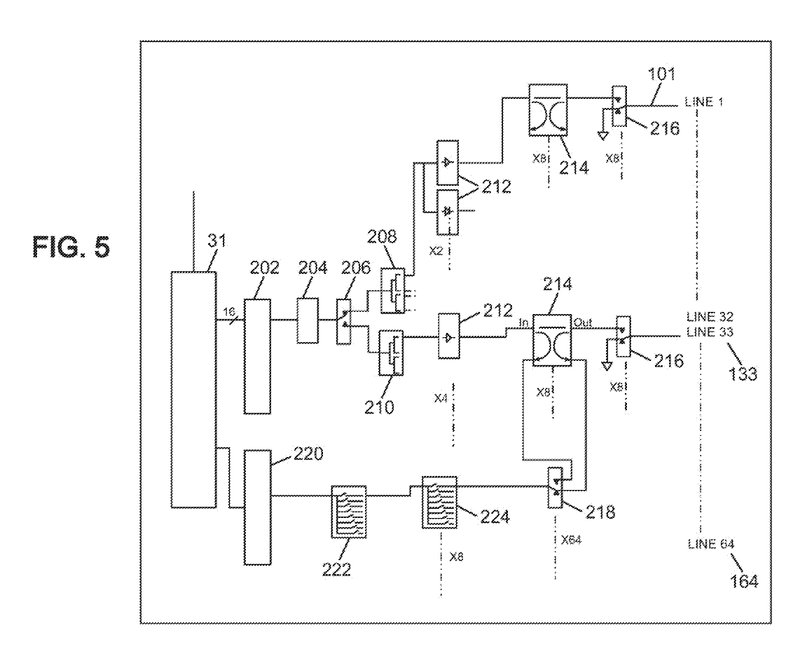

FIG. 5 shows one embodiment of the switching matrix 27 of FIG. 4 in more detail, with its connection to the control unit 31 represented on the left in FIG. 5.

FIG. 5 illustrates only sixty-four channels 101 to 164. The diagram illustrated in this figure can be repeated sixteen times for the device described in the present description. The control unit 31 is thus connected to sixteen analog-to-digital convertors or ADC 202, of which only one is shown here. The ADC 202 is connected, for example by an RF output and a corresponding cable, to a programmable output attenuator 204 in order to control a first switch 206 to route between a first splitter 208 which will correspond to thirty-two channels (101 to 132) and a second splitter 210 which will correspond to the other thirty-two other channels (133 to 164).

Each channel has an amplifier 212 but also a bidirectional coupler 214 which is connected to a grounding first switch 216 on the one hand and to a second switch 218 on the other hand.

The first switch 216 thus enables grounding each channel. The second switch 218 is provided to enable routing a return signal to the control unit 31. There is thus located, between the set (sixty-four here) of second switches 218 and the control unit 31, an analog-to-digital converter or ADC 220, a first diverter 222 having eight switches in the present numerical example which are each connected to a second diverter 224 also having eight switches each.

FIG. 5 clearly shows that each of the sixty-four channels represented is independent. Due to the grounding first switch 216, the bidirectional coupler 214, and the second switch 218 or output switch, it is possible to:

independently bias the unused channels to ground or not,

generate a signal on one channel, and measure on this same channel or on one of the sixty-three other channels,

generate signals on multiple channels, for example up to sixty-three channels, and measure on one channel, for example the sixty-fourth.

If the diagram of FIG. 5 is repeated sixteen times, we then have 1024 completely autonomous channels. These are then 1024 channels that may or may not be biased to ground. We can also generate a signal on one of these channels and measure on another, or generate a signal on N channels and measure on one channel to be defined.

As shown in FIG. 5, an analog signal (echo, waveform, etc.) is sent on a channel after being generated by the control unit 31 (for example an FPGA control unit) and converted by the ADC 202.

One embodiment provides that a computer 32 comprising a software interface allows remotely controlling the fault detection process. The device and the computer 32 are connected by a wired network, for example Ethernet, or wireless network such as WIFI. The computer 32 allows simplifying the implementation of the method while controlling the type of measurement and the number and length of the wires to be tested. In one particular embodiment, the computer 32 is a tablet.

It is thus possible to configure the device so that it is adapted to its use and to the tests to be performed.

It is possible to execute reflectometry operations. The waveform and programmable gains are then adapted to the length of cable to be tested. Generation of a signal on one channel and measurement on another channel allows obtaining coupling (crosstalk) measurements. It is also possible to send a signal on one channel and measure on other channels in a sequenced manner, or to generate signals on sixty-three channels and measure on a sixty-fourth, in order to map a cable.

In another advantageous embodiment of the invention, a memory 33 external or internal to the computer 32 is configured to allow the implementation of storing step 20 and storing step 22. This memory 33 is connected to the computer 32 to enable the computer to perform comparison step 21 and comparison step 23.

There is also an embodiment of the invention that allows an LCR type of measurement in order to determine integrity and to characterize a set of wires 25, and thus determine the presence of a permanent fault.

To do this, the unit 24 comprises for example an LCR meter 34. The LCR meter 34 is connected to each first input end of the wires in the set of wires 25, via an LCR switching matrix 35 comprising at least as many output channels as there are wires to be tested. The LCR matrix 35 further comprises two input channels for connecting the LCR meter 34 to two wires to be characterized. The LCR matrix 35 also allows connecting to ground 36 the wires not being characterized, thereby avoiding the creation of parasitic capacitance. The outlet ends of the wires in the set of wires 25 are not connected to loads but are left in their environment.

In one embodiment, the LCR matrix 35 includes a plurality of solid state relays.

The LCR meter 34 and the LCR matrix 35 are advantageously controlled by the control unit 31.

The LCR meter 34 advantageously allows obtaining resistive measurements, measurements of inductance, and/or capacitive measurements. The method for characterizing the set of wires 25 using the LCR meter 34 preferably comprises a generation step, an acquisition and measurement step, and an analysis step.

According to one advantageous embodiment of the invention, the unit 24 also comprises an autonomous internal power supply (not shown) such as a battery. Thus the unit 24, which may be in the form of a portable tester, may advantageously be brought on location, for example to airport runways.

The fault detection device may advantageously be configured in a self-testing mode, allowing it to calibrate itself and determine if one of its own components has faults.

The invention thus enables detecting intermittent faults in a set of wires. In addition, the invention advantageously allows the detection of permanent faults.

In one advantageous embodiment, the invention also allows locating faults.

The method and means described enable fault detection without requiring any manual manipulation or even any user interaction between the different test steps.

The invention provides an effective and inexpensive means of prevention for a set of wires. The act of storing measurements makes it possible to detect a weakening wire and to identify when a fault is recurring too often at the same location. Indeed, if the power of the first return signal of a current measurement differs from the power of the return signals of the stored preceding measurements, but without reaching the fault detection threshold, the user can then be informed that a fault may soon be occurring in that cable. Advantageously, a first power measurement is made when the cable is produced. It is then possible to have a stored baseline when the set of wires 25 is first tested.

In addition, if multiple faults occur too often at the same location, the user can be informed of this and can check why that location is generating faults.

In the foregoing description, the fault detection is performed on a set of wires comprising single strand wires, but the present invention can also detect faults on other types of wires such as twisted wires or coaxial cables with a simple wire which use the wire and shielding as connection points.

One embodiment of the invention provides for carrying out the first test phase on all wires in the set of wires to be tested, and once a fault is detected the second test phase is carried out directly on the wire having impaired integrity, then once the fault is located, the first test phase can resume on the next wire. However, in an alternative embodiment of the invention, the first test phase may be continuous and test all wires in the set of wires, and only then carrying out the second test phase on the wires characterized as having impaired integrity.

The invention has applications for example in wire testing applications in the field of aeronautics, but it may also have applications in various fields such as industrial equipment, energy, and transport.

Of course, the invention is not limited to the preferred embodiment and the alternative embodiments presented above by way of non-limiting examples. It also relates to alternative embodiments within the reach of the skilled person which fall within the scope of the following claims.

1. A method for detecting faults in a set of wires (25) to be tested comprising at least two test wires each having a first end, the input end, and a second end, the output end, the method uses:
a signal generator (26),
an electrical ground (36),
a switching matrix (27) providing a plurality of channels respectively connected to the input ends of the wires to be tested, and whose function is to connect the wires to be tested either to the electrical ground (36) or to the signal generator (26) and to select only one of the channels for analysis of a return signal,
a set of end loads (28) connected to the output ends of each wire,
an acquisition unit (29) adapted for measuring the return signal,
an analysis unit (30), and
a control unit (31),
wherein the method comprises the following steps in succession:
selecting and connecting (10) at least one wire to be analyzed to the signal generator (26), and grounding the other wires,
generating (12) a test signal on the wire to be analyzed, using the signal generator (26),
measuring (13) the power of a first return signal on at least one connected wire, using the acquisition unit (29),
analyzing (14) the power of the return signal on the wire to be analyzed, using the analysis unit (30), and
determining the integrity of the wire undergoing analysis,
and wherein said steps are repeated automatically, changing the wire to be tested each time.

2. The method according to claim 1, comprising the following successive steps if at least one wire of the set of wires (25) is diagnosed as having impaired integrity:
generating (17) a location signal on a wire diagnosed as having impaired integrity, using the signal generator (26),
measuring (18) a second return signal on said wire diagnosed as having impaired integrity, using the acquisition unit (29),
analyzing (19) said wire diagnosed as having impaired integrity, by reflectometry, using the analysis unit (30), and
determining a position of the fault in said wire diagnosed as having impaired integrity.

3. The method according to claim 2, wherein determining the position of the fault is achieved by at least one of:
frequency shifting the return signal based on a frequency-modulated location signal,
time shifting the propagation of the return signal based on a location signal in pulse form,
pulse compression of the return signal based on a frequency-modulated location signal truncated by a gate function.

4. The method according to claim 1, wherein the generated test signal is a low frequency signal, in particular between 500 kHz and 5 MHz.

5. The method according to claim 1, wherein it stores a measurement of the return signals relative to the test signals is stored for each tested wire.

6. The method according to claim 1, wherein the acquired measurement is compared to measurements already stored during previous tests, enabling preventive maintenance for the set of wires.

7. The method according to claim 1, wherein it LCR meter (34) and an LCR switching matrix (35) having a set of channels respectively connected to the input ends of the wires to be tested is used, and whose function is to connect the wires to be tested either to the electrical ground (36) or to the LCR meter (34), and wherein
the method comprises the following steps in succession:
selecting at least two wires to be analyzed and connecting them to the LCR meter (34), and grounding the other wires,
generating a measurement signal using the LCR meter (34),
measuring at least one of: the resistance; the inductance or the capacitance, and
characterizing the wires undergoing analysis.

8. A fault detection device, comprising the necessary means for implementing all the steps of a fault detection method according to claim 1.

9. The device according to claim 8, further comprising:
a signal generator (26),
an electrical ground (36),
a switching matrix (27) providing a set of channels respectively connected to the input ends of the wires to be tested, and whose function is to connect the wires to be tested either to the electrical ground (36) or to the signal generator (26) and to select only one of the channels for analysis of a return signal,
a set of end loads (28) connected to the output ends of each wire,
an acquisition unit (29) adapted for measuring the return signal,
an analysis unit (30), and
a control unit (31).

10. The device according to claim 9, wherein the switching matrix (27) is a high frequency switching matrix having a set of channels respectively connected to the input ends of the wires to be tested, whose function is to connect the wires to be tested either to the electrical ground (36) or to the signal generator (26) and to select only one of the channels for analysis of a return signal.

11. The device according to claim 10, wherein each channel has a bidirectional coupler associated on the one hand with a grounding switch and on the other hand with an output switch.

12. The device according to claim 9, wherein the switching matrix (27) comprises at least one FET transistor operating as a switch.

13. The device according to claim 8 further comprising a computer (32) having a software interface which allows remotely controlling the fault detection method.

14. The device according to claim 8 further comprising an LCR meter (34) connected by means of an LCR switching matrix (35) to the set of wires (25) to be tested, which allows characterization of the set of wires (25) by at least one of: resistance measurements; inductance measurements or capacitance measurements.

15. A portable tester, comprising a fault detection device according to claim 8.
